(19) United States
(12) Patent Application Publication
(10) Pub. No.: US 2020/0295076 A1
(43) Pub. Date: Sep. 17, 2020

(54) IMAGE SENSOR AND THE MANUFACTURING METHOD THEREOF

(71) Applicant: Silicon Optronics, Inc., Hsinchu (TW)

(72) Inventor: Bo-Ray LEE, Hsinchu (TW)

(21) Appl. No.: 16/533,390

(22) Filed: Aug. 6, 2019

(30) Foreign Application Priority Data
Mar. 14, 2019 (TW) 108108604

(51) Int. Cl. H01L 27/146

(52) U.S. Cl. CPC H01L 27/14656; H01L 27/14689; H01L 27/1463

(57) ABSTRACT

An image sensor includes a semiconductor substrate, a first annular doped area, a second annular doped area, an annular isolation area, a photoelectric conversion area, a voltage conversion area, and a gate structure. The first annular doped area is disposed in the semiconductor substrate and includes a first type dopant. The second annular doped area is disposed in the semiconductor substrate, and over the first annular doped area, the second annular doped region includes a second type dopant. The annular isolation area is disposed in the semiconductor substrate and over the second annular doped area. The photoelectric conversion area is disposed in the semiconductor substrate surrounded by the annular isolation area. The voltage conversion area is disposed in the semiconductor substrate surrounded by the annular isolation area. The gate structure is disposed on the semiconductor substrate.

### CROSS REFERENCE TO RELATED APPLICATIONS

This Application claims priority of Taiwan Patent Application No. 108108604, filed on Mar. 14, 2019, the entirety of which is incorporated by reference herein.

### TECHNICAL FIELD

The present disclosure relates to an image sensor, and in particular, to an image sensor that can reduce blooming and electrical crosstalk.

### BACKGROUND

In semiconductor technology, an image sensor is used to sense light irradiated onto a semiconductor substrate. Conventional image sensors such as the complementary metal oxide semiconductor (CMOS) image sensor and the charge coupled device (CCD) image sensor are widely used in electronic devices such as digital cameras for capturing images or recording video.

An image sensor has a plurality of pixels. When the light is irradiated on the pixels of the image sensor, the electrons are excited in the image sensor, and the electrons accumulate in the photodiode (PD) of the pixel. Specifically, electrons accumulate in the capacitance formed by the photodiode. However, if the excited electrons are close to the edge of the pixel, the electrons may cross to another pixel and accumulate in the photodiode of the other pixel. This phenomenon is called electrical crosstalk. In addition, if the electrons that have accumulated in the photodiode of the pixel exceed the amount that the photodiode is able to accumulate (i.e., the amount of electrons that the photodiode can store, also known as the full well capacity), the electrons will also cross to other pixels. This phenomenon is called blooming. The electrical crosstalk and the blooming can affect the image displayed by an electronic device (e.g., a digital camera).

In order to prevent blooming, an overflow gate or a surface overflow drain may be formed in some image sensors. However, the overflow gate or the surface overflow drain may reduce the full well capacity of the image sensor, without improving the electrical crosstalk. Therefore, in the present technology, a vertical overflow drain (VOD) is formed in the image sensor to drive out excess electrons (or absorb excess electrons), thereby preventing electrical crosstalk and blooming. However, the vertical overflow drain usually sacrifices the quantum efficiency (QE) of the image sensor and does not completely improve the blooming. Therefore, an image sensor having a new structure is required.

### SUMMARY

The present disclosure provides an image sensor. The image sensor includes a semiconductor substrate, a first annular doped area, a second annular doped area, an annular isolation area, a photoelectric conversion area, a voltage conversion area, and a gate structure. The first annular doped area is disposed in the semiconductor substrate, wherein the first annular doped area comprises a first type dopant. The second annular doped area is disposed in the semiconductor substrate and over the first annular doped area, the second annular doped region comprises a second type dopant. The annular isolation area is disposed in the semiconductor substrate and over the second annular doped area. The photoelectric conversion area is disposed in the semiconductor substrate surrounded by the annular isolation area. The voltage conversion area is disposed in the semiconductor substrate surrounded by the annular isolation area. The gate structure is disposed on the semiconductor substrate.

The present disclosure provides a method of manufacturing an image sensor. The method includes forming a first annular doped area in a semiconductor substrate, the first annular doped area comprises a first type dopant; forming a second annular doped area in the semiconductor substrate, the second annular doped area comprises a second type dopant; forming an annular isolation area in the semiconductor substrate; forming a gate structure on the semiconductor substrate; forming a photoelectric conversion area in the semiconductor substrate; and forming a voltage conversion area in the semiconductor substrate, wherein the photoelectric conversion area and the voltage conversion area are surrounded by the annular isolation area.

The present disclosure provides a method of manufacturing an image sensor. The method includes forming an annular isolation area in a semiconductor substrate; forming a trench area in the annular isolation area; forming a first annular doped area in the semiconductor substrate, the first annular doped area comprises a first type dopant; forming a second annular doped area in the semiconductor substrate, the second annular doped area comprises a second type dopant; forming an isolation structure in the trench area; forming a gate structure on the semiconductor substrate; forming a photoelectric conversion area in the semiconductor substrate; and forming a voltage conversion area in the semiconductor substrate.

### BRIEF DESCRIPTION OF DRAWINGS

In order to describe the manner in which the above-recited features and other advantages of the disclosure can be obtained, a more particular description of the principles briefly described above will be rendered by reference to specific examples thereof which are illustrated in the appended drawings. It should be understood that these drawings depict only exemplary aspects of the disclosure and are therefore not to be considered to be limiting of its scope. The principles herein are described and explained with additional specificity and detail through the use of the accompanying drawings, in which:

FIG. 1 illustrates a cross-sectional view of a portion of a structure in an image sensor, in accordance with some embodiments of the present disclosure.

FIG. 2 illustrates a cross-sectional view of a portion of an image sensor having a vertical overflow drain (VOD), in accordance with some embodiments of the present disclosure.

FIG. 3 illustrates a top view of an image sensor having an annular P-type doped area and an annular N-type doped area, in accordance with some embodiments of the present disclosure

FIG. 4 illustrates a cross-sectional view of a portion of an image sensor having an annular P-type doped area and an annular N-type doped area, in accordance with some embodiments of the present disclosure.

FIGS. 5A to 5G illustrate cross-sectional views of formation of a portion of an image sensor, in accordance with some embodiments of the present disclosure.

FIGS. 6A to 6H illustrate cross-sectional views of another formation of a portion of an image sensor, in accordance with some embodiments of the present disclosure.

FIG. 7 illustrates a global shutter image sensor having the partial VOD, in accordance with some embodiments of the present disclosure.

FIG. 8 illustrates a global shutter image sensor having the partial VOD, in accordance with some embodiments of the present disclosure, wherein a polycrystalline gate structure is on a storage node.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

For purposes of the present detailed description, unless specifically disclaimed, the singular includes the plural and vice versa; and the word “including” means “including without limitation.” Moreover, words of approximation, such as “about,” “almost,” “substantially,” “approximately,” and the like, can be used herein to mean “at, near, or nearly at,” or “within 3-5% of,” or “within acceptable manufacturing tolerances,” or any logical combination thereof, for example.

Furthermore, spatially relative terms, such as “beneath,” “below,” “lower,” “above,” “upper” and the like, may be used herein for ease of description to describe one element or feature's relationship to another element or feature as illustrated in the figures. The spatially relative terms are intended to encompass different orientations of the device in. use or operation in addition to the orientation depicted in the figures. For example, if the device in the figures is turned over elements described as being “below” or “beneath” other elements or features would then be oriented “above” the other elements or features. Thus, the exemplary term “below” can encompass both an orientation of above and below. The apparatus may be otherwise oriented (rotated 90 degrees or at other orientations) and the spatially relative descriptors used herein may likewise be interpreted accordingly.

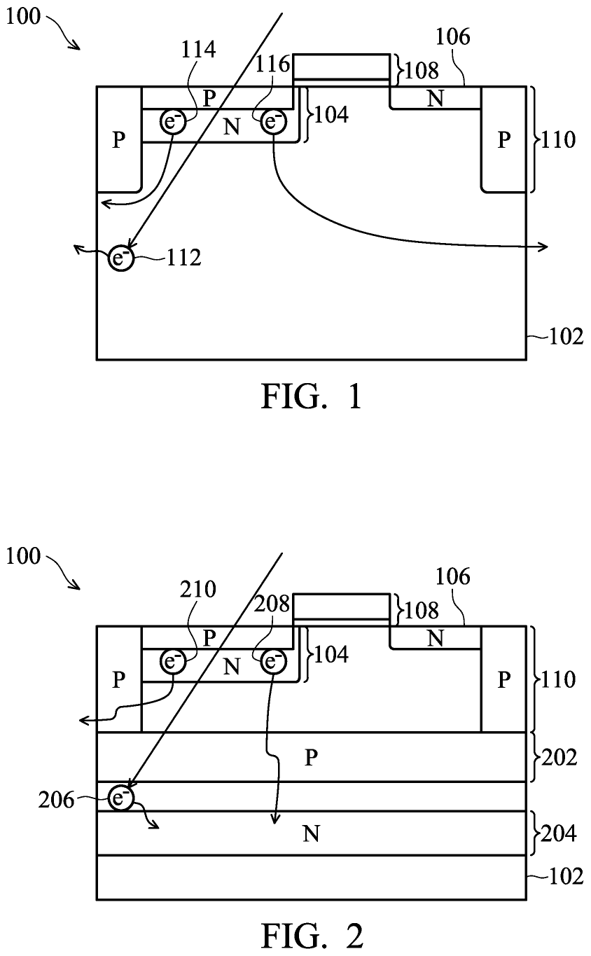

FIG. 1 illustrates a cross-sectional view of a portion of a structure in an image sensor, in accordance with some embodiments of the present disclosure. The semiconductor structure 100 is a structure of one pixel of the image sensor. The semiconductor structure 100 includes a semiconductor substrate 102, a photoelectric conversion area 104, a voltage conversion area 106, a gate structure 108, and an isolation area 110.

The semiconductor substrate 102 may be a bulk semiconductor, a semiconductor-on-insulator (SOI) substrate, or the like, which may be doped (e.g., with P-type dopants (e.g., Boron) or N-type dopants (e.g., Phosphorus)) or undoped. The semiconductor substrate 102 may be a wafer, such as a silicon wafer. In some embodiments, the semiconductor substrate 102 may include an elementary semiconductor (e.g., silicon, germanium, and diamond), a compound semiconductor (e.g., silicon carbide, gallium arsenic, gallium phosphide, indium phosphide, indium arsenide, indium antimonide, or the like), an alloy semiconductor (e.g., SiGe, GaAsP, AlInAs, AlGaAs, GalnAs, GaInP, GaInAsP, or the like), another kind of semiconductor material, or combinations thereof. In some embodiments, the semiconductor substrate 102 may also include an epitaxial layer on bulk semiconductor, a silicon germanium layer on bulk silicon, a silicon layer on bulk silicon germanium, etc. In other embodiments, the semiconductor substrate 102 may also include an epitaxial layer doped with P-type or N-type dopants.

The photoelectric conversion area 104 is formed in the semiconductor substrate 102. The photoelectric conversion area 104 may include a photoelectric conversion element, such as a photodiode (PD). Specifically, the photoelectric conversion area 104 includes a P-type doped layer and an N-type doped layer formed by an ion implantation process. In other embodiments, the photoelectric conversion area 104 may include other types of photoelectric conversion elements.

The voltage conversion area 106 is formed in the semiconductor substrate 102. The voltage conversion area 106 may include a floating diffusion (FD) area, which may be considered as a voltage conversion element, such as a capacitive structure. Specifically, after electrons accumulated in the photoelectric conversion area 104 are moved to the voltage conversion area 106 by applying a voltage to the gate structure 108, the electrons may be accumulated in the voltage conversion area 106 (i.e., a capacitance structure), and the accumulated electrons have (generate) a voltage value. By reading this voltage value, an image sensed by the image sensor can be generated. in this embodiment, the voltage conversion area 106 has N-type dopants. Specifically, the voltage conversion area 106 is formed by implanting the N-type dopants into the semiconductor substrate 102 by performing an ion implantation process.

The gate structure 108 is fainted on the semiconductor substrate 102 between the photoelectric conversion area 104 and the voltage conversion area 106. The gate structure 108 may include a gate dielectric layer and a gate electrode. The gate dielectric layer may be silicon oxide, silicon nitride, multilayers thereof, or the like, and may be deposited or thermally grown according to acceptable techniques. The formation methods of the gate dielectric layer may include molecular-beam deposition (MBD), atomic layer deposition (ALD), plasma-enhanced chemical vapor deposition (PECVD), chemical vapor deposition (CVD), or thermal oxidation, and the like. The gate electrode may be formed of single crystal silicon or polycrystalline silicon, but may be formed by using other materials. In some embodiments, the material of the gate electrode may include a metal-containing material such as titanium nitride (TiN), tantalum nitride (TaN), tantalum carbide (TaC), cobalt (Co), ruthenium (Ku), aluminum (Al), combinations thereof, or multi-layers thereof. The gate structure 108 may also be referred to as a transfer gate.

The isolation area 110 is formed in the semiconductor substrate 102 and surrounds the photoelectric conversion area 104, the voltage conversion area 106, and the gate structure 108 (i.e., the photoelectric conversion area 104, the voltage conversion area 106, and the gate structure 108 are in the semiconductor substrate 102 surrounded by the isolation area 110). Therefore, the isolation area 110 may also be referred to as an annular isolation area (in top view). The area surrounded by the isolation area 110 is referred to as a pixel area of the image sensor.

When the light is irradiated on the semiconductor structure 100 of the image sensor, electrons are excited. The electrons are accumulated in the capacitance formed by the photoelectric conversion area 104. However, if the excited electrons are close to the edge of the pixel, the electrons may cross to another pixel and accumulate in the photodiode of another pixel (e.g., the electron 112 of FIG. 1). This phenomenon is called electrical crosstalk. In addition, if the electrons accumulated in the photoelectric conversion area 104 exceed the amount that the photoelectric conversion area 104 can accumulate (the photoelectric conversion area 104 is saturated) (i.e., the amount of the electrons that the photodiode can store, also referred to as full well capacity), the electrons will also cross to another pixel ((e.g., the electron 114 and the electron 116 of FIG. 1). This phenomenon is called blooming. Therefore, a vertical overflow drain (VOD) is formed in the image sensor to prevent the electrical crosstalk and the blooming, as shown in FIG. 2.

FIG. 2 illustrates a cross-sectional view of a portion of an image sensor having a vertical overflow drain (VOD), in accordance with some embodiments of the present disclosure. The vertical overflow drain has a P-type doped area 202 and an N-type doped area 204 additionally formed in the semiconductor structure 100. The P-type doped area 202 includes P-type dopants and the N-type doped area 204 includes N-type dopants. The P-type dopants and the N-type dopants are implanted into the semiconductor substrate 102 by performing an ion implantation process. The N-type doped area 204 is connected to a positive voltage to absorb excess electrons. For example, as shown in FIG. 2, the electron 206 excited near the edge of the semiconductor structure 100 is absorbed by the N-type doped area 204. Therefore, the electron 206 does not cross to another pixel, avoiding the electrical crosstalk.

The P-type doped area 202 may be selectively formed, and the P-type doped area 202 may maintain the quantum efficiency (QE) of the image sensor and block the electrons. However, if the electrons accumulated in the photoelectric conversion area 104 are excessive (saturated), the electrons still have a probability to cross the P-type doped area 202 and the isolation area 110. If the electrons cross the P-type doped area 202, the electrons are absorbed by the N-type doped area 204, the blooming will not occur, as shown by the electron 208. If the electrons cross the isolation area 110 to another pixel, the blooming will still occur, as shown by the electron 210. Therefore, in the present embodiment, instead of the P-type doped area 202 and the N-type doped area 204, an annular P-type doped area and an annular N-type doped area are formed to improve the blooming and still prevent the electrical crosstalk.

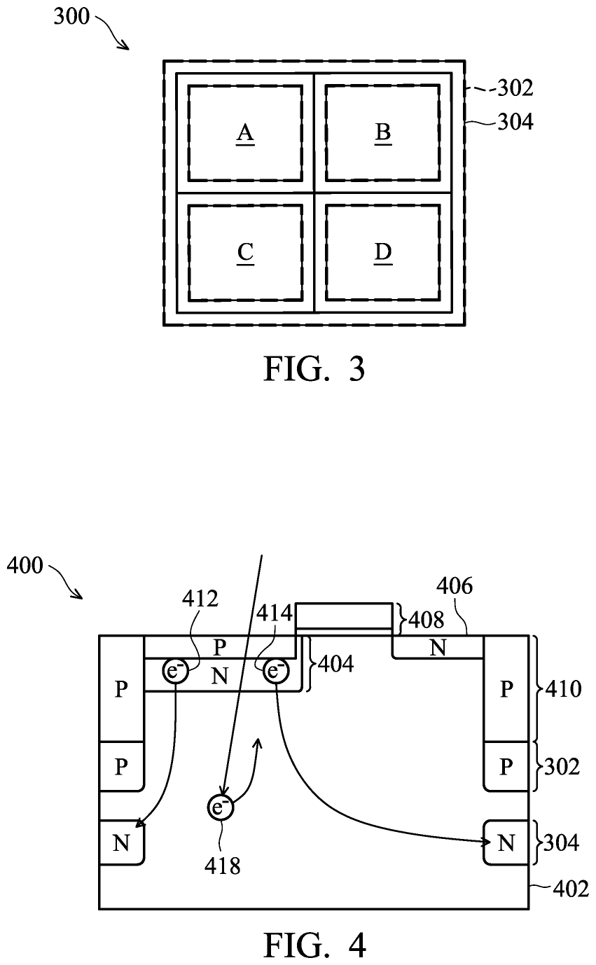

FIG. 3 illustrates a top view of an image sensor having an annular P-type doped area and an annular N-type doped area, in accordance with some embodiments of the present disclosure. In FIG. 3, pixels A, B, C, and D of the image sensor 300 are surrounded by an annular P-type doped area 302 and an annular N-type doped area 304 (the annular P-type doped area 302 and the annular N-type doped area 304 overlap). The annular P-type doped area 302 and the annular N-type doped area 304 may be referred to as a partial VOD, an annular VOD, or a grid like VOD.

FIG. 4 illustrates a cross-sectional view of a portion of an image sensor having an annular P-type doped area and an annular N-type doped area, in accordance with some embodiments of the present disclosure. The semiconductor structure 400 shows the structure of one pixel of the image sensor 300. The semiconductor structure 400 includes a semiconductor substrate 402, a photoelectric conversion area 404, a voltage conversion area 406, a gate structure 408, and an isolation region 410. These elements are similar to the semiconductor substrate 102, the photoelectric conversion area 104, the voltage conversion area 106, the gate structure 108, and the isolation region 110, and will not be described herein in detail. The semiconductor structure 400 further includes an annular P-type doped area 302 and an annular N-type doped area 304. The annular P-type doped area 302 includes P-type dopants, the annular P-type doped area 302 is formed in the semiconductor substrate 102 and below the isolation area 410. The annular N-type doped area 304 includes N-type dopants, the annular N-type doped area 304 is formed in the semiconductor substrate 102 and below the annular P-type doped area 302. The annular N-type doped area 304 is connected to a positive voltage. The P-type dopants and the N-types dopants are implanted in the annular P-type doped area 302 and the annular N-type doped area 304 by performing an ion implantation process.

As shown in FIG. 4, the annular P-type doped area 302 does not completely block the electrons. When the electrons accumulated in the photoelectric conversion area 404 are excessive (saturated), the electrons easily move downward (e.g., electrons 412 and 414), thereby being absorbed by the annular N-type doped area 304, avoiding occurrence of the blooming and the electrical crosstalk. The annular N-type doped area 304 is not formed directly below the photoelectric conversion area 404, the voltage conversion area 406, and the gate structure 408, so that the electron 418 excited in the semiconductor substrate 402 is not absorbed, but move upward to accumulate in the photoelectric conversion region 404 (the electrons accumulated in the photoelectric conversion area 404 are not excessive (not saturated)). If the electrons in the photoelectric conversion area 404 are excessive (saturated), the electrons 418 are absorbed by the annular N-type doped area 304. Therefore, compared to a conventional image sensor having a vertical overflow drain (compared to the quantum efficiency reduction caused by the N-type doped area 204), the quantum efficiency reduction of the image sensor caused by the annular N-type doped area 304 is less.

In some embodiments, a portion of the annular P-type doped area 302 and a portion of the annular N-type doped area 304 extend and are directly under the photoelectric conversion area 404 and the voltage conversion area 406 for adjusting some characteristics of the image sensor (e.g., the quantum efficiency, the electron absorption, etc.).

In some embodiments, a shallow trench isolation (STI) structure (i.e., an isolation structure) (not shown) is formed in the isolation area 410 to further reduce the influence between pixels of the image sensor.

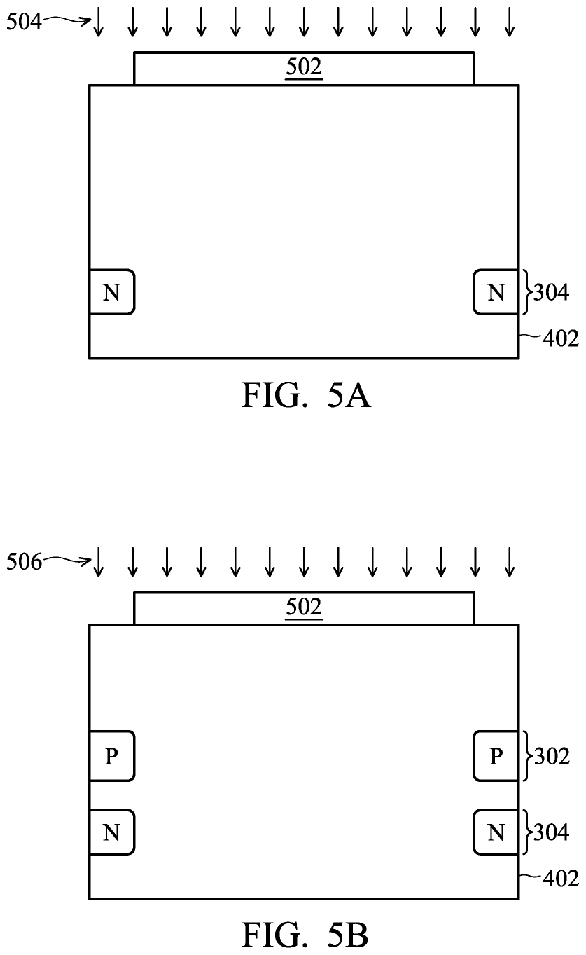

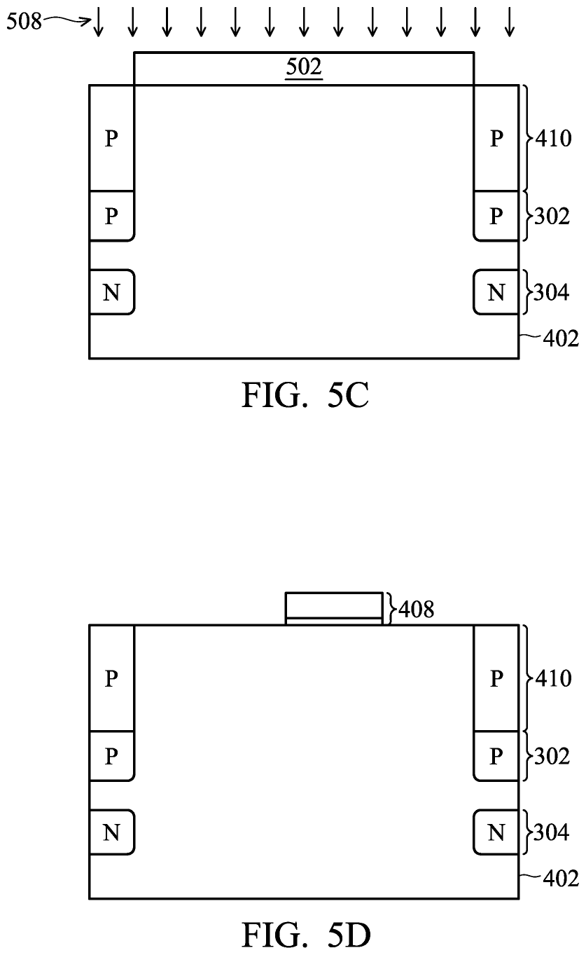

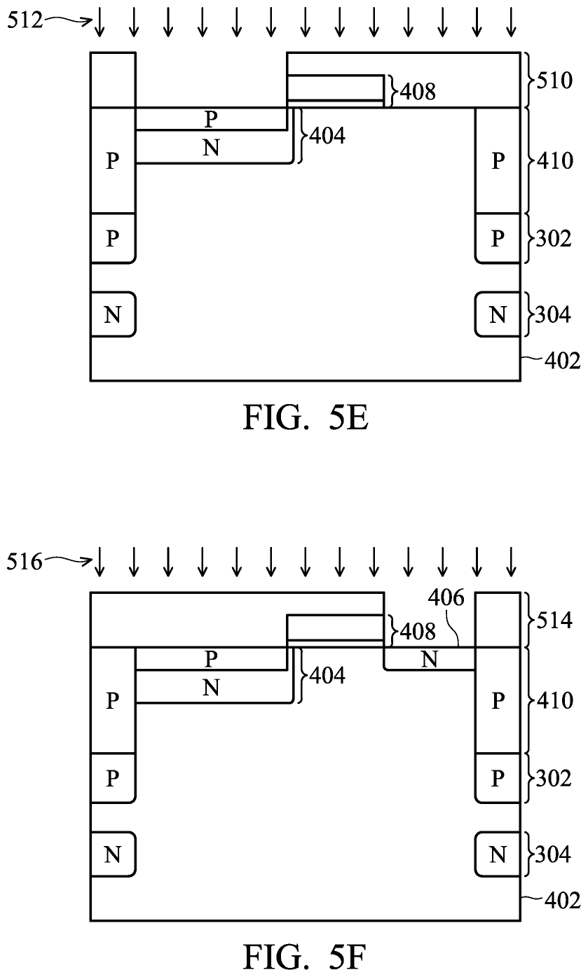

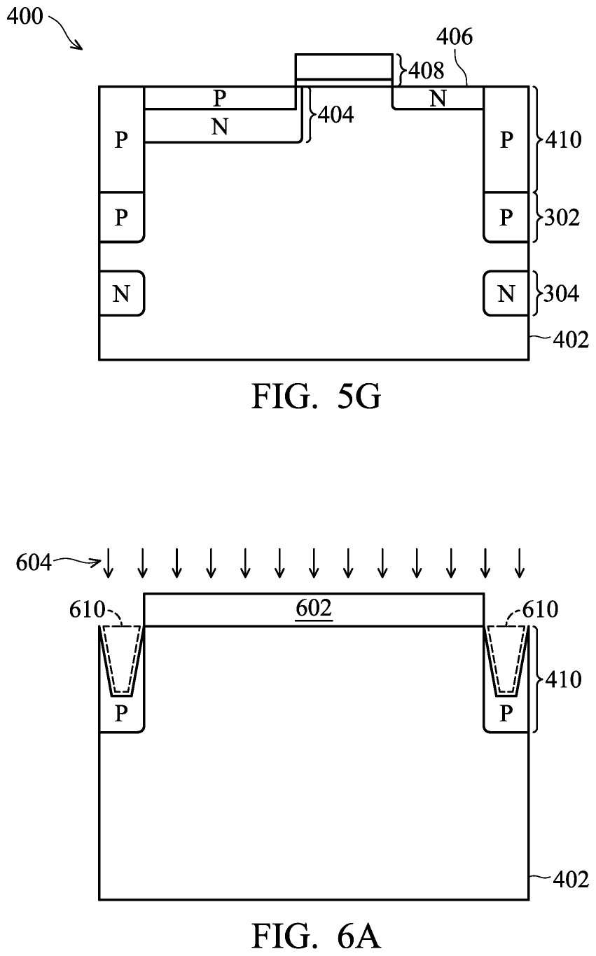

FIGS. 5A to 5G illustrate cross-sectional views of formation of a portion of an image sensor, in accordance with some embodiments of the present disclosure. In FIG. 5A, a photoresist 502 is formed on the semiconductor substrate 402 by a lithography process. Then, N-type dopants are implanted into the semiconductor substrate 402 by performing an ion implantation process 504 to form the annular N-type doped area 304.

In FIG. 5B, P-type dopants are implanted into the semiconductor substrate 402 by performing an ion implantation process 506 to form the annular P-type doped area 302 over the annular N-type doped region 304.

In FIG. 5C, P-type dopants are implanted into the semiconductor substrate 402 by performing an ion implantation process 508 to form the isolation area 410 over the annular P-type doped area 302.

It should be noted that the annular P-type doped area 302, the annular N-type doped area 304, and the isolation area 410 are all formed by the ion implantation process with the photoresist 502 as a mask on the semiconductor substrate 402. Therefore, the annular P-type doped area 302, the annular N-type doped area 304, and the isolation area 410 overlap each other. Furthermore, since no additional processing steps are required to form the photoresist for forming the annular P-type doped area 302 and the annular N-type doped area 304, the process cost is not increased as compared with the conventional process.

In some embodiments, the annular P-type doped area 302, the annular N-type doped area 304, and the isolation area 410 are respectively formed with different photoresists. The annular P-type doped area 302, the annular N-type doped area 304, and the isolation region 410 do not completely overlap each other.

In some embodiments, a shallow trench isolation structure is formed in the isolation area 410. Specifically, after the isolation area 410 is formed, a trench is formed in the isolation area 410 by an etching process. Silicon oxide (SiO2) is then deposited by a deposition process (e.g., chemical vapor deposition (CVD), plasma-enhanced chemical vapor deposition (PECVD), high density plasma chemical vapor deposition (HDP-CVD), etc.) to form the shallow trench isolation structure.

In some embodiments, the annular P-type doped area 302 and the isolation area 410 are formed by the same ion implantation process. Specifically, after the annular N-type doped area 304 is formed, the annular P-type doped area 302 and the isolation area 410 are simultaneously formed by only one ion implantation process. In other words, the annular P-type doped area 302 and the isolation area 41.0 are the same area. This process method can reduce process costs.

In FIG. 5D, after the photoresist 502 is removed, a gate dielectric layer is formed on the semiconductor substrate 402 by a deposition process (e.g., plasma-enhanced chemical vapor deposition or chemical vapor deposition, etc.) or an oxidation process (e.g., thermal oxidation), and a gate electrode is formed on the gate dielectric layer by a lithography process and a deposition process (e.g., chemical vapor deposition or physical vapor deposition, etc.) to form the gate structure 408.

In FIG. 5E, a photoresist 510 is formed on the semiconductor substrate 402 by a lithography process. The N-type dopants and the P-type dopants are then implanted into the semiconductor substrate 402 by performing an ion implantation process 512 to form the photoelectric conversion area 404.

In FIG. 5F, after the photoresist 510 is removed, a photoresist 514 is formed on the semiconductor substrate 402 by a lithography process. The N-type dopants are implanted into the semiconductor substrate 402 by performing an ion implantation process 516 to form a voltage conversion area 406.

In FIG. 5G, after the photoresist 514 is removed, the image sensor 300 is completely formed (FIG. 5G shows the semiconductor structure 400 of one pixel of the image sensor 300).

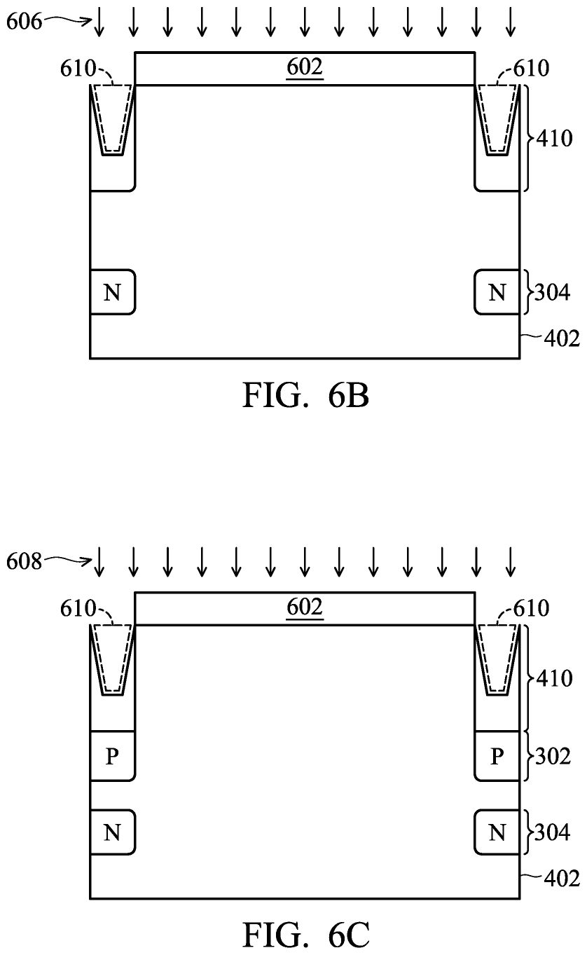

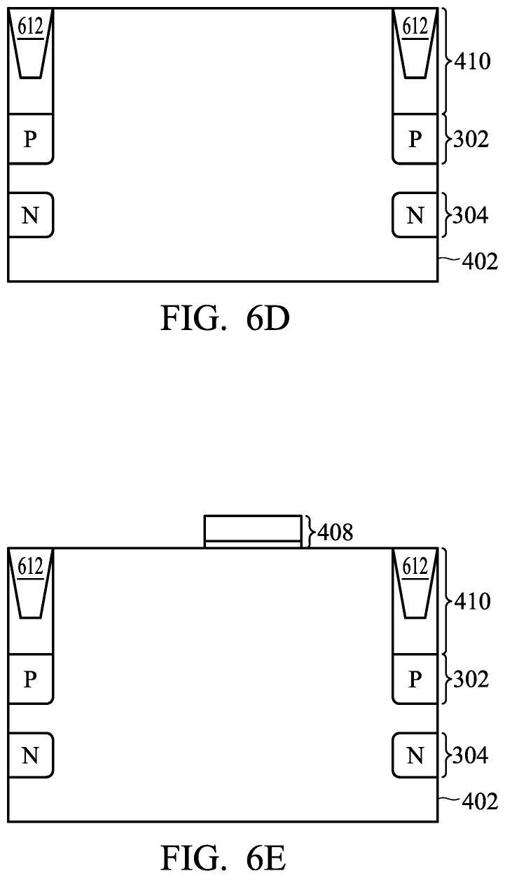

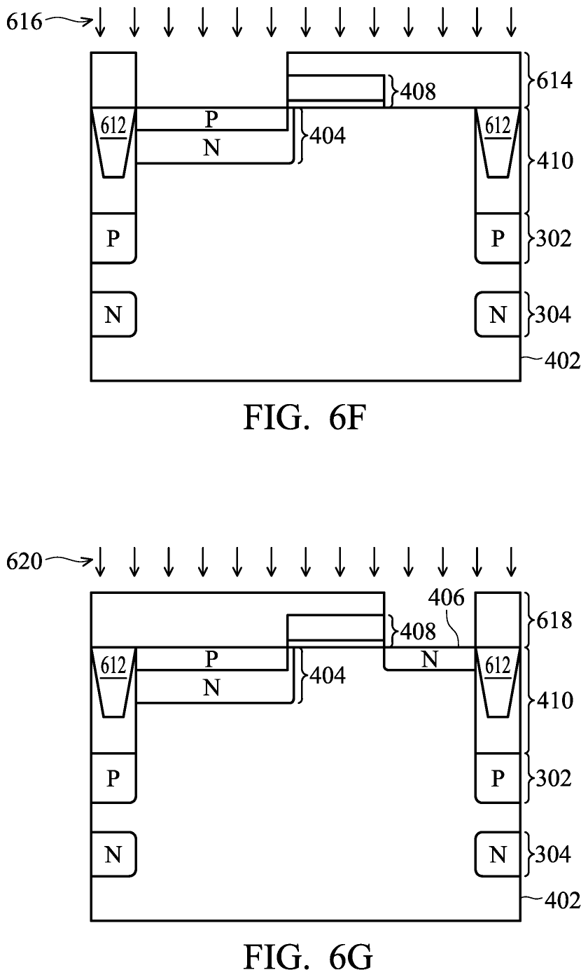

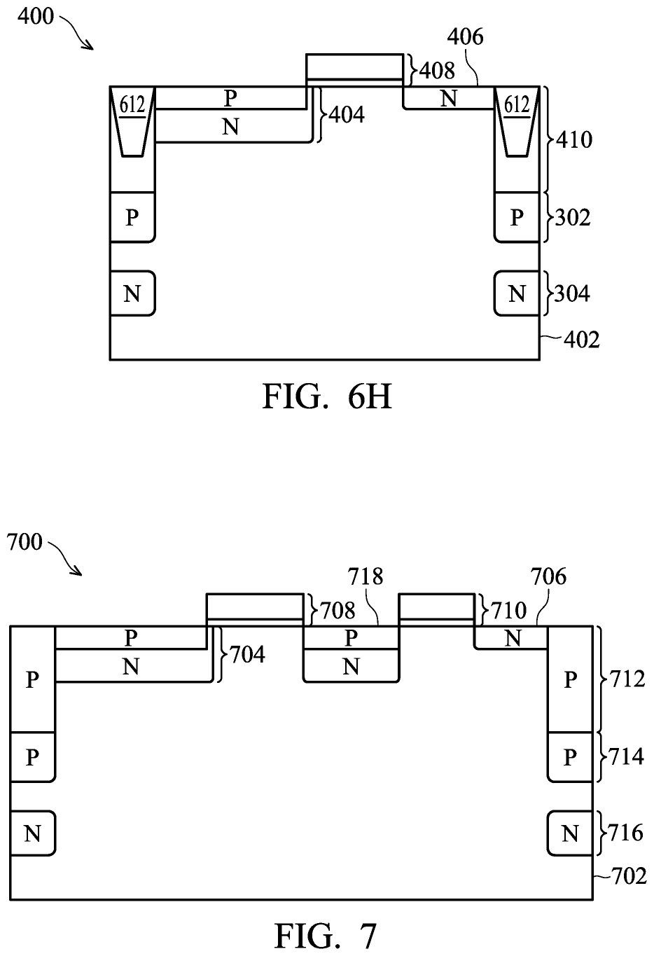

In some embodiments, the annular P-type doped area 302, the annular N-type doped area 304, and the isolation area 410 may be formed by another process sequence. FIGS. 6A to 6H illustrate cross-sectional views of another formation of a portion of an image sensor, in accordance with some embodiments of the present disclosure. In FIG. 6A, a photoresist 602 is formed on the semiconductor substrate 402 by a lithography process. Next, after a trench area 610 is formed in the semiconductor substrate 402 by an etching process, the P-type dopants are implanted into the semiconductor substrate 402 by performing an ion implantation process 604 to form the isolation area 410.

In FIG. 6B, the N-type dopants are implanted into the semiconductor substrate 402 by performing an ion implantation process 606 to form the annular N-type doped area 304.

In FIG. 6C, the P-type dopants are implanted into the semiconductor substrate 402 by performing an ion implantation process 608 to form the annular P-type doped area 302 over the annular N-type doped area 304.

In FIG. 6D, silicon oxide (SiO2) is deposited in the trench area 610 by a deposition process. Excess silicon oxide and photoresist 602 are then removed to form isolation structure 612 (i.e., shallow trench isolation).

It should be noted that the annular P-type doped area 302 and the annular N-type doped area 304 are formed with the isolation area 410 having the trench area 610. In this case, the distance from the surface of the semiconductor substrate 402 to the position where the annular P-type doped area 302 and the annular N-type doped area 304 are to be formed is smaller. Therefore, the annular P-type doped area 302 and the annular N-type doped area 304 can be formed using a lower energy ion implantation process or less process time, and the formed annular P-type doped area 302 and the formed annular N-type doped area 304 will have a relatively narrow width (i.e., the annular P-type doped area 302 and the annular N-type doped area 304 are not easy to be formed/extended/diffused below the subsequently formed photoelectric conversion region 404 and voltage conversion region 406).

In FIG. 6E, a gate dielectric layer is formed on the semiconductor substrate 402 by a deposition process (e.g., plasma-enhanced chemical vapor deposition or chemical vapor deposition, etc.) or an oxidation process (e.g., thermal oxidation), and a gate electrode is formed on the gate dielectric layer by a lithography process and a deposition process (e.g., chemical vapor deposition or physical vapor deposition, etc.) to form the gate structure 408.

In FIG. 6F, a photoresist 614 is formed on the semiconductor substrate 402 by a lithography process. The N-type dopants and the P-type dopants are then implanted into the semiconductor substrate 402 by performing an ion implantation process 616 to form the photoelectric conversion area 404.

In FIG. 6G, after the photoresist 614 is removed, a photoresist 618 is formed on the semiconductor substrate 402 by a lithography process. The N-type dopants are implanted into the semiconductor substrate 402 by performing an ion implantation process 620 to form a voltage conversion area 406.

In FIG. 6H, after the photoresist 618 is removed, the image sensor 300 is completely formed (FIG. 6H shows the semiconductor structure 400 of one pixel of the image sensor 300). In this embodiment, the image sensor 300 (semiconductor structure 400) has an isolation structure 612.

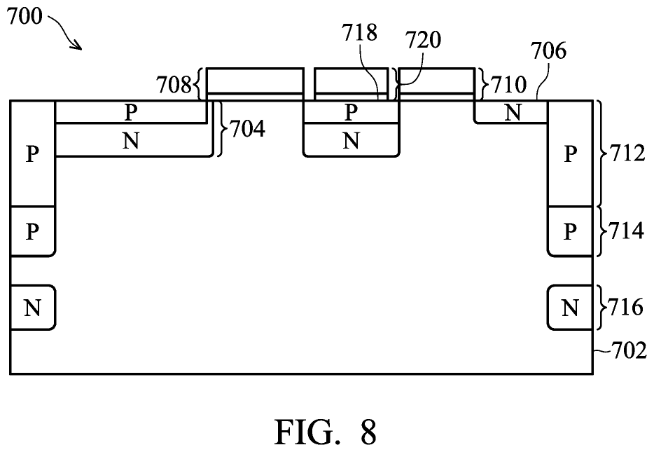

The structure shown in the present embodiments of the disclosure is a rolling shutter structure. However, the partial VOD (the annular P-type doped area and the annular N-type doped area) of the present embodiments may also be applied to a global shutter structure. FIG. 7 illustrates a global shutter image sensor having the partial VOD, in accordance with some embodiments of the present disclosure. The semiconductor structure 700 shows a structure of one pixel of the image sensor. The semiconductor structure 700 includes a semiconductor substrate 702, a photoelectric conversion area 704, a voltage conversion area 706, gate structures 708 and 710, an isolation area 712, an annular P-type doped area 714, an annular N-type doped area 716, and a storage node 718. The annular N-type doped area 716 is formed below the isolation area 712. The annular P-type doped area 714 is formed below isolation region 712 and over the annular N-type doped area 716. The photoelectric conversion area 704, the voltage conversion area 706, and the storage node 718 are formed in the semiconductor substrate 702 surrounded by the isolation area 712. The gate structures 708 and 710 are formed on the semiconductor substrate 702. In some embodiments, there is an isolation structure (shallow trench isolation) in the isolation area 712 that is similar to the isolation structure 612 in FIG. 6H. In this embodiment, the storage node 718 is a P-N junction structure. In other embodiments, there is a polycrystalline gate structure on the storage node 718, as shown in a polycrystalline gate structure 720 of FIG. 8.

The above embodiments are applied to a P-type substrate or a P-type well (e.g., the semiconductor substrate 402 is a P-type substrate or a P-type well area). However, it should be understood that the technique of the present disclosure may also be applied to an N-type substrate or an N-type well. In this case, the doping type of the P-type doped area and the N-type doped area of the above embodiment is reversed.

The embodiments of the present disclosure offer advantages over existing art, though it should be understood that other embodiments may offer different advantages, not all advantages are necessarily discussed herein, and that no particular advantage is required for all embodiments.

By utilizing the embodiments of the present disclosure, an image sensor having a partial vertical overflow drain (also referred to as an annular vertical overflow drain or a grid like vertical overflow drain) can be formed. Compared to conventional image sensors having a generally vertical overflow drain, the image sensor of the present embodiments can prevent blooming and does not reduce quantum efficiency.

The terminology used herein is for the purpose of describing particular embodiments only, and is not intended to be limiting of the invention. As used herein, the singular forms “a”, “an” and “the” are intended to include the plural forms as well, unless the context clearly indicates otherwise. Furthermore, to the extent that the terms “including,” “includes,” “having,” “has,” “with,” or variants thereof, are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art. Furthermore terms, such as those defined in commonly used dictionaries, should be interpreted as having a meaning that is consistent with their meaning in the context of the relevant art, and will not be interpreted in an idealized or overly formal sense unless expressly so defined herein.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
a semiconductor substrate;
a first annular doped area, disposed in the semiconductor substrate, wherein the first annular doped area comprises a first type dopant;
a second annular doped area, disposed in the semiconductor substrate and over the first annular doped area, wherein the second annular doped region comprises a second type dopant;
an annular isolation area, disposed in the semiconductor substrate and over the second annular doped area;
a photoelectric conversion area, disposed in the semiconductor substrate surrounded by the annular isolation area;
a voltage conversion area, disposed in the semiconductor substrate surrounded by the annular isolation area; and
a gate structure, disposed on the semiconductor substrate.

2. The image sensor as claimed in claim 1, further comprising:
an isolation structure, disposed in the annular isolation area and over the second annular doped area.

3. The image sensor as claimed in claim 1, wherein the first annular doped area, the second annular doped area, and the annular isolation area overlap each other.

4. The image sensor as claimed in claim 1, wherein the photoelectric conversion area comprises a photodiode (PD).

5. The image sensor as claimed in claim 1, wherein the voltage conversion area comprises a floating diffusion (FD) area.

6. A method of manufacturing an image sensor, comprising:
forming a first annular doped area in a semiconductor substrate, wherein the first annular doped area comprises a first type dopant;
forming a second annular doped area in the semiconductor substrate, wherein the second annular doped area comprises a second type dopant;
forming an annular isolation area in the semiconductor substrate;
forming a gate structure on the semiconductor substrate;
forming a photoelectric conversion area in the semiconductor substrate; and
forming a voltage conversion area in the semiconductor substrate, wherein the photoelectric conversion area and the voltage conversion area are surrounded by the annular isolation area.

7. The method as claimed in claim 6, further comprising:
forming an isolation structure in the annular isolation area.

8. The method as claimed in claim 6, wherein the first annular doped area, the second annular doped area, and the annular isolation area overlap each other.

9. A method of manufacturing an image sensor, comprising:
forming an annular isolation area in a semiconductor substrate;
forming a trench area in the annular isolation area;
forming a first annular doped area in the semiconductor substrate, wherein the first annular doped area comprises a first type dopant;
forming a second annular doped area in the semiconductor substrate, wherein the second annular doped area comprises a second type dopant;
forming an isolation structure in the trench area;
forming a gate structure on the semiconductor substrate;
forming a photoelectric conversion area in the semiconductor substrate; and
forming a voltage conversion area in the semiconductor substrate.

10. The method as claimed in claim 9, wherein the first annular doped area, the second annular doped area, and the annular isolation area overlap each other.
